(19) United States
(12) Patent Application Publication
(10) Pub. No.: US 2004/0242015 A1
(43) Pub. Date: Dec. 2, 2004

(54) Etching compositions for silicon germanium and etching methods using the same

(76) Inventors: Kyoung-Chul Kim, Gyeonggi-do (KR); Dong-Gun Park, Gyeonggi-do (KR); Yong-Sun Ko, Gyeonggi-do (KR); In-Seak Hwang, Gyeonggi-do (KR); Byoung-Moon Yoon, Gyeonggi-do (KR); Sung-Min Kim, Incheon-si (KR); Jeong-Dong Choe, Gyeonggi-do (KR)

Correspondence Address: MYERS BIGEL SIBLEY & SAJOVEC, PO BOX 37428, RALEIGH, NC, 27627, US

(21) Appl. No.: 10/793,437

(22) Filed: Mar. 4, 2004

(30) Foreign Application Priority Data
Mar. 4, 2003 (KR) 2003-11310
Mar. 4, 2003 (KR) 2003-13394

(51) Int. Cl. H01L 21/20; H01L 21/36; C09K 13/00

(52) U.S. Cl. 438/753; 438/752; 252/79.1

(57) ABSTRACT

Etching compositions for selectively etching silicon germanium faster than other silicon containing compositions may be produced by controlling the ratios of de-ionized water used in the etching compositions with respect to the amounts of nitric acid, hydrofluoric acid, and/or acetic acid. Methods for selectively etching silicon germanium without damaging a silicon substrate or a silicon layer are possible using the etching compositions.

### CROSS REFERENCE TO RELATED APPLICATIONS

This application claims priority from Korean Patent Application No. 2003-11310 filed on Mar. 4, 2003, which is incorporated herein by reference in its entirety.

### FIELD OF THE INVENTION

This invention relates to etching compositions for semiconductor devices and methods of etching semiconductor devices. More particularly, the present invention relates to etching compositions for etching silicon germanium having a high selectivity for silicon germanium with respect to silicon.

### BACKGROUND OF THE INVENTION

As advances in semiconductor technology have occurred, semiconductor devices have become highly integrated in order to process large amounts of information at faster rates and using different techniques. Accordingly, the intervals between patterns and pattern widths in semiconductor devices and integrated circuits have become narrower in order to increase the number of patterns that may be formed on a semiconductor substrate.

In particular, as the design rule of the semiconductor devices decreases to about 100 nm or less, the space for forming patterns gradually decreases. While the size of the pattern decreases, electron mobility plays an important role in the operation of the highly integrated semiconductor device. In addition, when a leakage current leaking from a source/drain region formed on a substrate to the lower portion of the substrate is generated, a considerable amount of current is leaked from the whole semiconductor device, thereby lowering the operational speed of the semiconductor device.

An insulation layer may be buried on the semiconductor substrate to help prevent the leakage of the current at the lower portion of the substrate. The buried insulation layer may be present under an active region of the substrate to prevent the movement of electrons to the lower portion of the substrate when a channel is formed within a semiconductor device and electrons move from the source/drain region. The substrate having a buried insulation layer may be formed by burying an insulation layer on a silicon wafer and growing silicon on the buried insulation layer. Silicon germanium may be used for forming buried insulation layers.

When a silicon nitride layer or a silicon oxide layer is formed on a silicon wafer of single crystal silicon, subsequent single crystal silicon layers may not be grown. Accordingly, silicon germanium can be applied on the silicon nitride layer or the silicon oxide layer.

In order to selectively form a silicon germanium layer on an active region, the silicon germanium layer can be etched with a higher selectivity with respect to silicon. In addition, methods for removing the silicon germanium layer with a high selectivity are desired.

A widely known selective etching solution for silicon germanium is SC-1, which includes ammonium hydroxide (NH₄OH), hydrogen peroxide (H₂O₂) and deionized water (H₂O). According to a wet etching method using SC-1, the selectivity of silicon germanium with respect to silicon can be controlled according to variations in applied temperature and time. However, due to hydrogen peroxide (H₂O₂) in the SC-1, the surface of the silicon germanium layer may be rapidly oxidized and generally an etch selectivity for silicon with respect to silicon germanium higher than about 1 to 20 is difficult to accomplish. Thus, when silicon germanium is etched to the desired degree using SC-1, the loss of silicon also increases.

Japanese Laid Open Patent Publication No. Hei13-148473 proposes a method of etching silicon germanium. According to it, silicon germanium can be etched using an etching solution including nitric acid, hydrofluoric acid and de-ionized water. The etching solution of Hei13-148473 has an etching selectivity for silicon to silicon germanium of about 1 to 2. As a result, when silicon germanium is etched using the etching solutions and methods of Hei13-148473, the silicon is also etched and a continuous etching occurs while being transferred to a rinsing process. This is undesirable because it results in an unnecessary loss of silicon.

In practice, therefore, it is desirable to obtain an etching solution having an etching selectivity for silicon to silicon germanium of about 1 to about 100 or more.

### SUMMARY OF THE INVENTION

Embodiments of the present invention relate to methods for etching silicon germanium and etching compositions that may be used to etch silicon germanium. According to embodiments of the present invention, etching compositions for etching silicon germanium include various amounts of nitric acid, hydrofluoric acid, and de-ionized water. In other embodiments, the etching compositions may also include acetic acid. Still other embodiments of the present invention include methods for etching silicon germanium and silicon using the etching compositions of the present invention.

According to some embodiments of the present invention, an etching composition having a high etching selectivity for silicon germanium with respect to silicon is provided by controlling the ratio of de-ionized water in the etching composition with respect to nitric acid, hydrofluoric acid, and acetic acid. For example, an etching composition may include nitric acid in an amount of about 35.4 percent to about 41.3 percent by weight, hydrofluoric acid in an amount of about 0.5 percent to about 0.6 percent by weight, acetic acid in an amount of about 1.1 percent to about 2.1 percent by weight, and de-ionized water in an amount of about 56 percent to about 63 percent by weight.

According to other embodiments of the present invention, an etching composition having a high etching selectivity for silicon germanium with respect to silicon is provided by controlling the ratio of de-ionized water in the etching composition with respect to nitric acid and hydrofluoric acid. For example, an etching composition may include nitric acid in an amount of about 35.4 percent to about 41.3 percent by weight, hydrofluoric acid in an amount of about 0.5 percent to about 0.6 percent by weight, and de-ionized water in an amount of about 41.9 percent to about 65.4 percent by weight.

In still other embodiments of the present invention, etching compositions having a high etching selectivity for silicon germanium with respect to silicon may be combined as a single etching solution or used sequentially to etch silicon germanium.

Embodiments of the present invention also relate to methods for selectively etching silicon germanium from semiconductor devices, integrated circuit devices, or other devices containing silicon germanium. According to the embodiments of the present invention, silicon germanium may be etched from semiconductor devices, integrated circuit devices, or other devices containing silicon germanium using an etching composition having a high etching selectivity for silicon germanium with respect to silicon. In addition, the methods of the present invention enable the selective etching of silicon germanium without damaging a neighboring silicon layer.

According to some embodiments of the present invention, a method of etching silicon germanium from a semiconductor device is provided. A silicon germanium layer and a silicon layer are formed on a silicon substrate. A portion of the silicon layer, the silicon germanium layer, and the silicon substrate are etched to expose cross-sectional portions of the layers and substrate. The cross-sectional portions of the layers and substrate are then exposed to an etching composition according to embodiments of the present invention to etch the silicon germanium layer faster than the silicon layer and the silicon substrate.

In other embodiments, an opening is formed in a semiconductor device by etching a portion of a silicon substrate. Silicon germanium is deposited in the opening to form a silicon germanium layer. An etching solution according to embodiments of the present invention is contacted with the exposed silicon substrate and silicon germanium to etch the silicon germanium faster than the silicon substrate. In still other embodiments, a silicon layer may also be deposited over the silicon substrate and silicon germanium layer. The etching of the silicon germanium layer using etching compositions according to embodiments of the present invention also proceeds faster than etching of the silicon layer.

### BRIEF DESCRIPTION OF THE DRAWING FIGURES

The invention can be more readily ascertained from the following description of the invention when read in conjunction with the accompanying drawings in which:

FIGS. 1A to 1D illustrate cross-sectional representations of a portion of a semiconductor device during various processing stages;

FIG. 2A illustrates a scanning electron microscope (SEM) image of a semiconductor device according to embodiments of the present invention; and

FIG. 2B illustrates a scanning electron microscope (SEM) image of a semiconductor device.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like numbers refer to similar or identical elements throughout. It will be understood that when an element such as a layer, region or substrate is referred to as being “on” or “onto” another element, it can be directly on the other element or intervening elements may also be present.

According to embodiments of the present invention, etching compositions for etching silicon germanium include various amounts of nitric acid, hydrofluoric acid, and de-ionized water. In other embodiments, the etching compositions may also include acetic acid. Still other embodiments of the present invention include methods for etching silicon germanium and silicon using the etching compositions of the present invention.

In some embodiments of the present invention, an etching composition includes nitric acid, hydrofluoric acid, and de-ionized water. The amount of nitric acid in the etching composition is about 35.4 percent to about 41.3 percent by weight. The amount of hydrofluoric acid in the etching composition is about 0.5 percent to about 0.7 percent by weight. The amount of de-ionized water in the etching composition is about 41.9 percent to about 65.4 percent by weight. The weight percentages of nitric acid, hydrofluoric acid, and de-ionized water in the etching composition are based upon the total weight of the etching composition.

It has been found that the use of nitric acid in amounts less than about 35.4 percent by weight with etching compositions of the present invention results in the retardation of the etching rate in semiconductor processes. When the amount of nitric acid in an etching composition of the present invention exceeds about 41.3 percent by weight of the etching composition, the selectivity of silicon germanium with respect to silicon for the etching solution is reduced. Although the rate of etching may be increased with the inclusion of more than about 41.3 percent by weight nitric acid in the etching compositions of the present invention, the selectivity of silicon germanium with respect to silicon for the etching composition is decreased, which is undesirable. Therefore, the etching compositions of the embodiments of the present invention include between about 35.4 percent to about 41.3 percent by weight nitric acid.

The hydrofluoric acid in the etching compositions may remove oxide layers formed on silicon germanium during the etching process. According to embodiments of the present invention, the etching composition includes hydrogen fluoride in an amount of about 0.5 percent to about 0.6 percent by weight based upon the total weight of the etching composition.

According to other embodiments of the present invention, an etching composition includes nitric acid, hydrofluoric acid, acetic acid, and de-ionized water. The amount of nitric acid in the etching composition is about 35.4 percent to about 41.3 percent by weight. The amount of hydrofluoric acid in the etching composition is about 0.5 percent to about 0.6 percent by weight. The amount of acetic acid in the etching composition is about 1.1 to about 2.1 percent by weight. The amount of de-ionized water in the etching composition is about 56 percent to about 63 percent by weight. The weight percentages of nitric acid, hydrofluoric acid, acetic acid and de-ionized water in the etching composition are based upon the total weight of the etching composition.

It has been found that the use of nitric acid in amounts less than about 35.4 percent by weight with etching compositions of the present invention results in the retardation of the etching rate in semiconductor processes. When the amount of nitric acid in an etching composition of the present invention exceeds about 41.3 percent by weight of the etching composition, the selectivity of silicon germanium with respect to silicon for the etching solution is reduced. Although the rate of etching may be increased with the inclusion of more than about 41.3 percent by weight nitric acid in the etching compositions of the present invention, the selectivity of silicon germanium with respect to silicon for the etching composition is decreased, which is undesirable. Therefore, the etching compositions of the embodiments of the present invention include between about 35.4 percent to about 41.3 percent by weight nitric acid.

The hydrofluoric acid in the etching compositions may remove oxide layers formed on silicon germanium during the etching process. According to embodiments of the present invention, the etching composition includes hydrogen fluoride in an amount of about 0.5 percent to about 0.6 percent by weight based upon the total weight of the etching composition.

The acetic acid in the etching composition may act as a buffer during the etching of silicon germanium. It has been found that when the amount of acetic acid in the etching composition is less than about 1.1 percent by weight of the etching composition, the buffering function is insignificant. Furthermore, it has been determined that when the amount of acetic acid in the etching composition exceeds about 2.1 percent by weight of the etching composition, the buffering function is not greatly improved. Therefore, the amount of acetic acid used with etching compositions according to embodiments of the present invention is preferably about 1.1 percent to about 2.3 percent by weight.

When acetic acid is used as a buffer with etching solutions of the present invention, de-ionized water is used as a diluting agent. It has been found that if the amount of de-ionized water used as a diluting agent with acetic acid is less than about 56 percent by weight, silicon is excessively etched, lowering the etching selectivity of the etching solution for silicon germanium with respect to silicon. In addition, if the amount of de-ionized water used as a dilution agent in an acetic acid containing etching solution is greater than about 63 percent by weight the rate of etching is increased. Therefore, acetic acid containing etching solutions according to embodiments of the present invention include about 56 percent to about 63 percent by weight de-ionized water.

According to other embodiments of the present invention, etching compositions of the present invention may be mixed together to form an etching composition or used sequentially or consecutively to etch a semiconductor device. For example, a first etching composition having about 35.4 percent to about 41.3 percent by weight nitric acid, about 0.5 percent to about 0.6 percent by weight hydrofluoric acid, and about 49.1 percent to about 65.4 percent by weight de-ionized water may be mixed with a second etching composition having about 35.4 percent to about 41.3 percent by weight nitric acid, about 0.5 percent to about 0.6 percent by weight hydrofluoric acid, about 1.1 to about 2.1 percent by weight acetic acid, and about 56 percent to about 63 percent by weight de-ionized water to form an etching composition of the present invention.

The etching compositions according to embodiments of the present invention exhibit an etching selectivity of silicon to silicon germanium of about 1 to 100 or more, respectively. The use of etching compositions having an etching selectivity of silicon to silicon germanium of 1 to less than 100 to etch semiconductor devices results in excessive etching of silicon on the semiconductor devices. The excessive etching of silicon results in the loss of silicon from the semiconductor device, which is undesired. Thus, the etching compositions according to embodiments of the present invention are preferably formed to exhibit etching selectivity of silicon to silicon germanium of about 1 to about 100 or more, respectively.

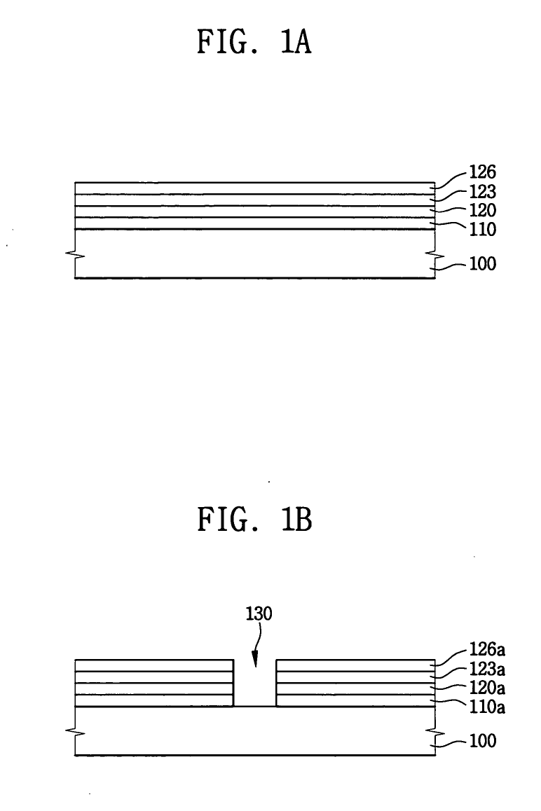

According to other embodiments of the present invention, a semiconductor device may be manufactured and/or etched using the etching compositions according to embodiments of the present invention. For example, a semiconductor device may be etched according to embodiments of the present invention as shown in FIGS. 1A to 1D, which illustrate cross-sectional views of a representative semiconductor device.

A semiconductor device, as illustrated in FIG. 1A, may include a silicon germanium layer 10, a silicon layer 120, an oxide layer 123, and a silicon nitride layer 126 formed on a silicon wafer 100. A portion of the silicon nitride layer 126 may be etched to expose the oxide layer 123 using, for example, an etching solution including phosphoric acid. The exposed portion of the oxide layer 123, as well as the silicon layer 120 and silicon germanium layer 110 under the exposed oxide layer 123 may be subsequently etched to form the structure illustrated in FIG. 1B. Upon etching, the semiconductor device, as illustrated in FIG. 1B, includes a silicon layer pattern 110a, a silicon germanium layer pattern 120a, an oxide layer pattern 123a, and a silicon nitride layer pattern 126a. The layer patterns define an open region 130 having side walls and exposing an upper surface portion of the silicon wafer 100.

The open region 130 may be buried or filled with silicon or other substance composition using a selective epitaxial growth (SEG) method to form an SEG layer 140 within the open region 130 as illustrated in FIG. 1C.

As illustrated in FIG. 1D, the oxide layer, silicon layer, silicon germanium layer and exposed silicon wafer may be further etched to form a structure on silicon wafer. To form the structure, a portion of the silicon nitride layer a predetermined distance from the SEG layer is etched to expose a portion of the oxide layer. After the exposed portion of the oxide layer is etched, the silicon layer and silicon germanium layer underlying the exposed portion of the oxide layer may be etched using an etching composition according to embodiments of the present invention. The etching of the exposed portion of the oxide layer, the silicon layer, and silicon germanium layer forms the structure illustrated in FIG. 1D because the etching results in the formation of opening 150. The etching composition according to embodiments of the present invention may also etch a portion of the silicon wafer. Thus, etching with an etching composition according to embodiments of the present invention exposes cross sections of the silicon nitride layer pattern, the oxide layer pattern, the silicon layer pattern, the silicon germanium layer pattern and the silicon substrate as illustrated in FIG. 1D.

According to other embodiments of the present invention, a silicon layer and a silicon germanium layer on a silicon substrate may be etched using etching compositions according to embodiments of the present invention. For example, a silicon layer may be formed on a silicon substrate. A portion of the silicon layer may be etched to form an opening in the silicon layer. Silicon germanium may be buried or deposited in the opening to form a silicon germanium layer. Both the silicon layer and the silicon germanium layer are exposed at the upper surface portion of the silicon substrate. An etching composition according to embodiments of the present invention may be used to selectively etch the silicon layer and the silicon germanium layer buried in the opening.

The following Examples are presented to illustrate various embodiments of the present invention and are not meant to limit the embodiments of the present invention in any way. The Comparative Examples are presented to demonstrate certain advantages of embodiments of the present invention but are not meant to limit the advantages of the embodiments of the present invention. In the Examples and Comparative Examples, the purity of nitric acid was about 70 percent, the purity of the hydrofluoric acid used was about 50 percent and the purity of the acetic acid was about 99.9 percent. In the Examples and Comparative Examples, the temperature of the etching composition was maintained at between about 20° C. and about 30° C.

### EXAMPLE 1

A semiconductor device was provided having a silicon wafer, a silicon germanium layer, and a silicon layer. The semiconductor device was etched by exposing the semiconductor device to an etching composition according to embodiments of the present invention for about 10 seconds. The etching exposed cross sections of the silicon layer, the silicon germanium layer, and the silicon wafer. The etching composition included about 45.6 percent by weight nitric acid, about 0.7 percent by weight hydrofluoric acid, about 2.3 percent by weight acetic acid and about 51.4 percent by weight of de-ionized water and was overflowed on the semiconductor device at about 25° C.

### EXAMPLE 2

A semiconductor device was provided having a silicon wafer, a silicon germanium layer, and a silicon layer. The semiconductor device was etched by exposing the semiconductor device to an etching composition according to embodiments of the present invention for about 20 seconds. The etching exposed cross sections of the silicon layer, the silicon germanium layer, and the silicon wafer. The etching composition included about 45.6 percent by weight nitric acid, about 0.7 percent by weight hydrofluoric acid, about 2.3 percent by weight acetic acid and about 51.4 percent by weight of de-ionized water and was overflowed on the semiconductor device at about 25° C.

### EXAMPLE 3

A semiconductor device was provided having a silicon wafer, a silicon germanium layer, and a silicon layer. The semiconductor device was etched by exposing the semiconductor device to an etching composition according to embodiments of the present invention for about 30 seconds. The etching exposed cross sections of the silicon layer, the silicon germanium layer, and the silicon wafer. The etching composition included about 45.6 percent by weight nitric acid, about 0.7 percent by weight hydrofluoric acid, about 2.3 percent by weight acetic acid and about 51.4 percent by weight of de-ionized water and was overflowed on the semiconductor device at about 25° C.

### EXAMPLE 4

A semiconductor device was provided having a silicon wafer, a silicon germanium layer, and a silicon layer. The semiconductor device was etched by exposing the semiconductor device to an etching composition according to embodiments of the present invention for about 10 seconds. The etching exposed cross sections of the silicon layer, the silicon germanium layer, and the silicon wafer. The etching composition included about 41.3 percent by weight nitric acid, about 0.6 percent by weight hydrofluoric acid, about 2.1 percent by weight acetic acid and about 56 percent by weight of de-ionized water and was overflowed on the semiconductor device at about 25° C.

### EXAMPLE 5

A semiconductor device was provided having a silicon wafer, a silicon germanium layer, and a silicon layer. The semiconductor device was etched by exposing the semiconductor device to an etching composition according to embodiments of the present invention for about 20 seconds. The etching exposed cross sections of the silicon layer, the silicon germanium layer, and the silicon wafer. The etching composition included about 41.3 percent by weight nitric acid, about 0.6 percent by weight hydrofluoric acid, about 2.1 percent by weight acetic acid and about 56 percent by weight of de-ionized water and was overflowed on the semiconductor device at about 25° C.

### EXAMPLE 6

A semiconductor device was provided having a silicon wafer, a silicon germanium layer, and a silicon layer. The semiconductor device was etched by exposing the semiconductor device to an etching composition according to embodiments of the present invention for about 30 seconds. The etching exposed cross sections of the silicon layer, the silicon germanium layer, and the silicon wafer. The etching composition included about 41.3 percent by weight nitric acid, about 0.6 percent by weight hydrofluoric acid, about 2.1 percent by weight acetic acid and about 56 percent by weight of de-ionized water and was overflowed on the semiconductor device at about 25° C.

### EXAMPLE 7

A semiconductor device was provided having a silicon wafer, a silicon germanium layer, and a silicon layer. The semiconductor device was etched by exposing the semiconductor device to an etching composition according to embodiments of the present invention for about 10 seconds. The etching exposed cross sections of the silicon layer, the silicon germanium layer, and the silicon wafer. The etching composition included about 38.6 percent by weight nitric acid, about 0.6 percent by weight hydrofluoric acid, about 2 percent by weight acetic acid and about 58.8 percent by weight of de-ionized water and was overflowed on the semiconductor device at about 25° C.

### EXAMPLE 8

A semiconductor device was provided having a silicon wafer, a silicon germanium layer, and a silicon layer. The semiconductor device was etched by exposing the semiconductor device to an etching composition according to embodiments of the present invention for about 20 seconds. The etching exposed cross sections of the silicon layer, the silicon germanium layer, and the silicon wafer. The etching composition included about 38.6 percent by weight nitric acid, about 0.6 percent by weight hydrofluoric acid, about 2 percent by weight acetic acid and about 58.8 percent by weight of de-ionized water and was overflowed on the semiconductor device at about 25° C.

### EXAMPLE 9

A semiconductor device was provided having a silicon wafer, a silicon germanium layer, and a silicon layer. The semiconductor device was etched by exposing the semiconductor device to an etching composition according to embodiments of the present invention for about 30 seconds. The etching exposed cross sections of the silicon layer, the silicon germanium layer, and the silicon wafer. The etching composition included about 38.6 percent by weight nitric acid, about 0.6 percent by weight hydrofluoric acid, about 2 percent by weight acetic acid and about 58.8 percent by weight of de-ionized water and was overflowed on the semiconductor device at about 25° C.

### EXAMPLE 10

A semiconductor device was provided having a silicon wafer, a silicon germanium layer, and a silicon layer. The semiconductor device was etched by exposing the semiconductor device to an etching composition according to embodiments of the present invention for about 10 seconds. The etching exposed cross sections of the silicon layer, the silicon germanium layer, and the silicon wafer. The etching composition included about 41.3 percent by weight nitric acid, about 0.6 percent by weight hydrofluoric acid, and about 58.1 percent by weight of de-ionized water and was overflowed on the semiconductor device at about 25° C.

### EXAMPLE 11

A semiconductor device was provided having a silicon wafer, a silicon germanium layer, and a silicon layer. The semiconductor device was etched by exposing the semiconductor device to an etching composition according to embodiments of the present invention for about 20 seconds. The etching exposed cross sections of the silicon layer, the silicon germanium layer, and the silicon wafer. The etching composition included about 41.3 percent by weight nitric acid, about 0.6 percent by weight hydrofluoric acid, and about 58.1 percent by weight of de-ionized water and was overflowed on the semiconductor device at about 25° C.

### EXAMPLE 12

A semiconductor device was provided having a silicon wafer, a silicon germanium layer, and a silicon layer. The semiconductor device was etched by exposing the semiconductor device to an etching composition according to embodiments of the present invention for about 30 seconds. The etching exposed cross sections of the silicon layer, the silicon germanium layer, and the silicon wafer. The etching composition included about 41.3 percent by weight nitric acid, about 0.6 percent by weight hydrofluoric acid, and about 58.1 percent by weight of de-ionized water and was overflowed on the semiconductor device at about 25° C.

### COMPARATIVE EXAMPLE 1

A semiconductor device was provided having a silicon wafer, a silicon germanium layer, and a silicon layer. The semiconductor device was etched by exposing the semiconductor device to an etching composition for about 10 seconds. The etching exposed cross-sections of the silicon layer, the silicon germanium layer, and the silicon wafer. The etching composition included about 49.5 percent by weight nitric acid, about 0.7 percent by weight hydrofluoric acid, about 2.5 percent by weight acetic acid and about 47.3 percent by weight of de-ionized water and was overflowed on the semiconductor device at about 25° C.

### COMPARATIVE EXAMPLE 2

A semiconductor device was provided having a silicon wafer, a silicon germanium layer, and a silicon layer. The semiconductor device was etched by exposing the semiconductor device to an etching composition for about 20 seconds. The etching exposed cross-sections of the silicon layer, the silicon germanium layer, and the silicon wafer. The etching composition included about 49.5 percent by weight nitric acid, about 0.7 percent by weight hydrofluoric acid, about 2.5 percent by weight acetic acid and about 47.3 percent by weight of de-ionized water and was overflowed on the semiconductor device at about 25° C.

### COMPARATIVE EXAMPLE 3

A semiconductor device was provided having a silicon wafer, a silicon germanium layer, and a silicon layer. The semiconductor device was etched by exposing the semiconductor device to an etching composition for about 30 seconds. The etching exposed cross-sections of the silicon layer, the silicon germanium layer, and the silicon wafer. The etching composition included about 49.5 percent by weight nitric acid, about 0.7 percent by weight hydrofluoric acid, about 2.5 percent by weight acetic acid and about 47.3 percent by weight of de-ionized water and was overflowed on the semiconductor device at about 25° C.

The samples produced according to Examples 1 through 12 and Comparative Examples 1 through 3 were cut along a cross-section to expose the silicon layer, the silicon germanium layer, and the silicon wafer.

The second cross-section of the samples was observed using a vertical scanning electron microscope (SEM) picture. The difference in etching amounts for silicon and silicon germanium were determined.

When silicon germanium is grown on single crystal silicon the silicon germanium grows with a strain because of the difference in lattice constants. The measurement of the thickness of a layer using an optical method requires an optical constant in accordance with a stain thereof and an impurity concentration. However, the difference in the optical constants of silicon and silicon germanium is insignificant, therefore the measurement of the thickness of those compositions is difficult if not impossible. In addition, the growing thickness of stained silicon germanium on silicon is limited by the concentration of germanium, thus, a general profile meter cannot be used to determine thickness.

The difference in etching amounts for silicon and silicon germanium in the Examples and Comparative Examples were determined from the SEM pictures. The amount of etching that occurred for each of the samples from Examples 1-12 and Comparative Examples 1-3, as determined from the SEM picture, is shown in Table I.

TABLE I

| | | | Selectivity |
|---|---|---|---|
| | Si etching | Si-Ge etching | (Si-Ge etching amount/ Si |
| | amount (Å) | amount (Å) | etching amount) |
| Example 1 | 2.7 | 2740 | 1014 |
| Example 2 | 15 | 5520 | 368 |
| Example 3 | 35 | 9800 | 280 |
| Example 4 | 0 | 1308 | 1308 |
| Example 5 | 5 | 1860 | 372 |
| Example 6 | 11 | 2964 | 269 |
| Example 7 | 0 | 324 | 324 |
| Example 8 | 2.1 | 707 | 336 |
| Example 9 | 6.4 | 988 | 154 |
| Example 10 | 0 | 1286 | 1286 |
| Example 11 | 5 | 1856 | 371 |
| Example 12 | 10 | 2935 | 293 |
| Comparative | 110 | 4950 | 45 |
| Example 1 | | | |
| Comparative | 237 | — | — |
| Example 2 | | | |
| Comparative | 346 | — | — |
| Example 3 | | | |

Referring to Table I, the compositions prepared by Examples 1 through 12 exhibit an etching selectivity for silicon with respect to silicon germanium of about 1 to 100 or more. In particular, the etching compositions used with Examples 4, 7, and 10 exhibit a very high etching selectivity for silicon germanium over silicon with little etching of silicon. The etching compositions used in the Examples exhibit characteristics that are desirable and meet the standards required for the manufacturing processes of semiconductor devices.

The etching compositions used with Comparative Examples 1 through 3 exhibit a very low etching selectivity of silicon germanium with respect to silicon. For example, the selectivity of silicon with respect to silicon germanium is about 1 to 45 in Comparative Example 1. In addition, the amount of silicon etched by the etching compositions of Comparative Examples 2 and 3 was greater than those of the Examples and the etching of silicon germanium was so excessive that it could not be observed using an SEM image enlarged picture. Therefore, the etching selectivity of the etching compositions used with the Comparative Examples is undesirable because the failure of a semiconductor device may be caused due to the excessive etching, increased silicon etching, and potential for defect generation caused by the excessive etching.

The cross-sections of the Examples and Comparative Examples were also observed in vertical SEM pictures and the characteristics of the cross-sections compared in Table II. In Table II, the ‘∘’ designations indicate that the surface of the silicon was not corroded or damaged and that the morphology was a homogeneous state; a good result. The ‘X’ designations indicate that the surface of the silicon was corroded or damaged and that the morphology was a non-homogeneous state; a bad result. Where a layer lifting phenomenon existed the designation ‘Generated’ is reflected in Table II.

TABLE II

| | Si layer surface | Layer lifting phenomenon |
|---|---|---|
| Example 1 | ◯ | No |
| Example 2 | ◯ | No |
| Example 3 | ◯ | No |
| Example 4 | ◯ | No |
| Example 5 | ◯ | No |
| Example 6 | ◯ | No |
| Example 7 | ◯ | No |
| Example 8 | ◯ | No |
| Example 9 | ◯ | No |
| Example 10 | ◯ | No |
| Example 11 | ◯ | No |
| Example 12 | ◯ | No |
| Comparative Example 1 | X | Generated |
| Comparative Example 2 | X | Generated |
| Comparative Example 3 | X | Generated |

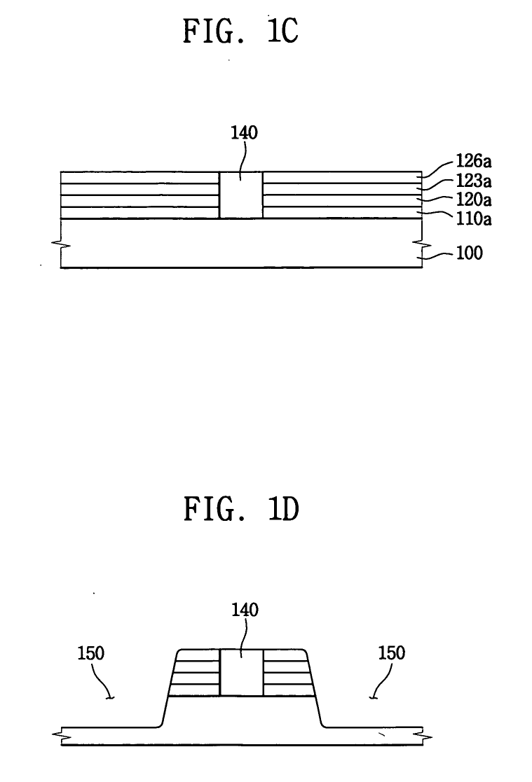

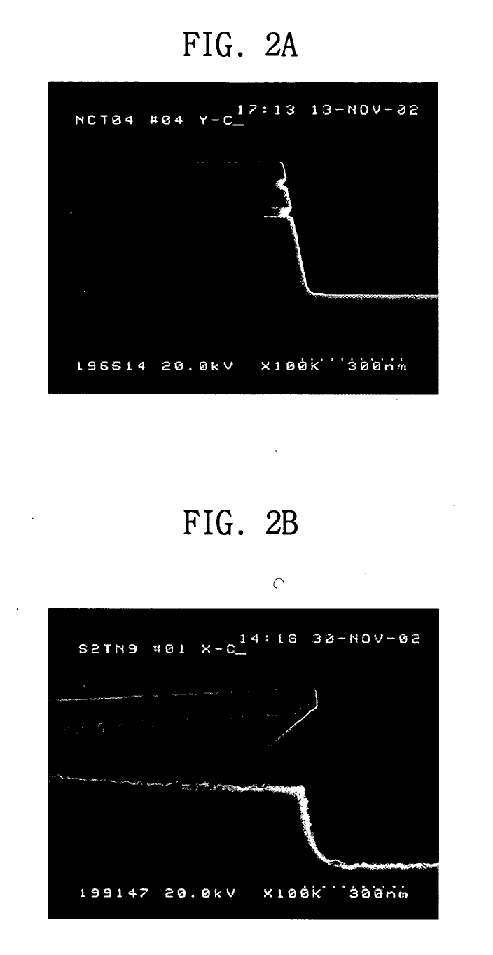

FIG. 2A is a cross-sectional SEM picture of a semiconductor device etched by an etching composition according to Example 6. Referring to FIG. 2A and Table II, the exposed surface portion of the silicon substrate is good when the etching composition of Example 6 was used. In addition, only the layer where silicon germanium was to be etched is etched and the other layers under the silicon germanium are not etched and are stable.

FIG. 2B is a cross-sectional SEM picture of a semiconductor device etched by an etching composition according to Comparative Example 3. Referring to FIG. 2B and Table II, the exposed surface of the silicon substrate is damaged and the morphology of the substrate is lowered as can be viewed by the naked eye. In addition, the etched amount of silicon germanium layer is excessive as demonstrated by the lack of a visible silicon germanium layer in FIG. 2B. Furthermore, a lifting phenomenon occurred, resulting in the lifting of the uppermost silicon nitride layer. The other layers positioned on the silicon germanium layer were also etched.

It has been found that the amount of de-ionized water based on the total amount of the etching composition is an important factor in determining the etching selectivity of the etching composition. Even though two similar etching compositions may be applied, the parts by weight of the constituting components of the etching compositions are important factors in determining the etching selectivity. For example, when the weight amount of de-ionized water increases, the etching amount of silicon and that of silicon germanium are decreased. When two etching compositions including the same weight amount of de-ionized water are used to etch a semiconductor, the etching amount is linearly and proportionally increased according to the etching time.

According to embodiments of the present invention, neighboring silicon layers and silicon germanium layers can be etched with a high selectivity of silicon germanium when applying an etching composition having appropriately controlled concentrations of nitric acid, hydrofluoric acid, acetic acid, and/or de-ionized water. In addition, the etching compositions of the present invention may not damage the silicon layer during etching.

The selective removal of a silicon germanium layer without unnecessarily damaging a silicon substrate or silicon layer can be achieved by using the etching compositions according to embodiments of the present invention when etching semiconductor devices.

Having thus described certain embodiments of the present invention, it is to be understood that the invention defined by the appended claims 1 is not to be limited by particular details set forth in the above description as many apparent variations thereof are possible without departing from the spirit or scope thereof as hereinafter claimed.

What is claimed is:

1. An etching composition, comprising:
about 35.4 percent to about 41.3 percent by weight nitric acid;
about 0.5 percent to about 0.6 percent by weight hydrofluoric acid; and
about 49.1 percent to about 65.4 percent by weight de-ionized water.

2. The etching composition of claim 1, wherein the etching selectivity of silicon with respect to silicon germanium for the etching composition is about 1 to 100 or more.

3. The etching composition of claim 1, further comprising about 1.1 percent to about 2.1 percent by weight acetic acid and wherein the percent by weight of de-ionized water is between about 56 percent to about 63 percent.

4. An etching composition, comprising:
about 35.4 percent to about 41.3 percent by weight nitric acid;
about 0.5 percent to about 0.6 percent by weight hydrofluoric acid;
about 1.1 percent to about 2.1 percent by weight acetic acid; and
about 56 percent to about 63 percent by weight de-ionized water.

5. The etching composition of claim 4, wherein the etching selectivity of silicon with respect to silicon germanium for the etching composition is about 1 to 100.

6. The etching composition of claim 4, wherein the etching selectivity of silicon with respect to silicon germanium for the etching composition is about 1 to 100 or more.

7. An etching composition, comprising a first etching composition and a second etching composition, wherein the first etching composition comprises about 35.4 percent to about 41.3 percent by weight nitric acid, about 0.5 percent to about 0.6 percent by weight hydrofluoric acid, and about 49.1 percent to about 65.4 percent by weight de-ionized water, and wherein the second etching composition comprises about 35.4 percent to about 41.3 percent by weight nitric acid, about 0.5 percent to about 0.6 percent by weight hydrofluoric acid, about 1.1 percent to about 2.1 percent by weight acetic acid, and about 56 percent to about 63 percent by weight de-ionized water.

8. The etching composition of claim 7, wherein the etching selectivity of silicon with respect to silicon germanium for the etching composition is about 1 to 100 or more.

9. A method for etching silicon germanium, comprising:
forming a silicon germanium layer and a silicon layer on a silicon substrate;
etching a portion of the silicon germanium layer, a portion of the silicon layer and the silicon substrate to expose cross-sectional portions of the silicon germanium layer, the silicon layer, and the silicon substrate; and
etching the silicon germanium layer faster than the silicon layer and the silicon substrate with an etching composition selected from the group consisting of a first etching composition, a second etching composition, and a mixture of the first etching composition and the second etching composition, wherein the first etching composition comprises about 35.4 percent to about 41.3 percent by weight nitric acid, about 0.5 percent to about 0.6 percent by weight hydrofluoric acid, about 1.1 percent to about 2.1 percent by weight acetic acid, and about 56 percent to about 63 percent by weight de-ionized water and wherein the second etching composition comprises about 35.4 percent to about 41.3 percent by weight nitric acid, about 0.5 percent to about 0.6 percent by weight hydrofluoric acid, and about 49.1 percent to about 65.4 percent by weight de-ionized water.

10. The method of claim 9, wherein the silicon germanium layer is etched at a rate of about 100 times faster than the silicon layer and the silicon substrate.

11. The method of claim 9, further comprising forming an oxide layer and a nitride layer on the silicon layer after forming the silicon layer.

12. The method of claim 9, wherein etching the silicon germanium layer is performed at a temperature between about 20° C. to about 30° C.

13. The method of claim 9, wherein forming a silicon germanium layer and a silicon layer on a silicon substrate further comprises:
forming the silicon germanium layer on the silicon substrate;
forming the silicon layer on the silicon germanium layer;
etching a portion of the silicon layer and the silicon germanium layer to form an opening exposing an upper surface of the silicon substrate; and
filling the opening with silicon.

14. A method for etching silicon germanium, comprising:
etching a portion of a silicon substrate to form an opening in the silicon substrate;
depositing silicon germanium in the opening to form a silicon germanium layer; and
etching the silicon germanium layer faster than the silicon substrate using an etching composition selected from the group consisting of a first etching composition, a second etching composition, and a mixture of the first etching composition and the second etching composition, wherein the first etching composition comprises about 35.4 percent to about 41.3 percent by weight nitric acid, about 0.5 percent to about 0.6 percent by weight hydrofluoric acid, about 1.1 percent to about 2.1 percent by weight acetic acid, and about 56 percent to about 63 percent by weight de-ionized water and wherein the second etching composition comprises about 35.4 percent to about 41.3 percent by weight nitric acid, about 0.5 percent to about 0.6 percent by weight hydrofluoric acid, and about 49.1 percent to about 65.4 percent by weight de-ionized water.

15. The method of claim 14, wherein the silicon germanium layer is etched at a rate about 100 times faster than the silicon substrate.

16. The method of claim 14, wherein etching the silicon germanium layer is performed at a temperature between about 20° C. and about 30° C.

17. The method of claim 14, further comprising depositing a silicon layer on the silicon substrate, wherein the silicon germanium layer is etched faster than the silicon layer.
